(19) United States
(12) Patent Application Publication
(10) Pub. No.: US 2025/0386712 A1
(43) Pub. Date: Dec. 18, 2025

(54) METHOD OF MANUFACTURING DISPLAY DEVICE, DISPLAY DEVICE, AND ELECTRONIC DEVICE COMPRISING DISPLAY DEVICE

(71) Applicant: Samsung Display Co., LTD., Yongin-si (KR)

(72) Inventor: Eun Kyung YEON, Yongin-si (KR)

(21) Appl. No.: 19/170,325

(22) Filed: Apr. 4, 2025

(30) Foreign Application Priority Data
Jun. 17, 2024 (KR) 10-2024-0078378
Jul. 18, 2024 (KR) 10-2024-0094744

(51) Int. Cl. H10K 59/80; H10K 59/12

(52) U.S. Cl. CPC H10K 59/873; H10K 59/1201; H10K 59/8792

(57) ABSTRACT

A method includes providing a display panel, combining a first jig with the display panel along a first combination direction, combining a second jig with the display panel along a second combination direction different from the first combination direction, and disposing a window layer including a resin material on the display panel.

This application claims priority to Korean Patent Application No. 10-2024-0078378, filed on Jun. 17, 2024, and Korean Patent Application No. 10-2024-0094744, filed on Jul. 18, 2024, and all the benefits accruing therefrom under 35 U.S.C. § 119, the content of which in their entirety is herein incorporated by reference.

### BACKGROUND

### 1. Field

The disclosure relates to a method of manufacturing a display device, the display device, and an electronic device comprising the display device.

### 2. Description of the Related Art

Recently, as interest in information display is increased, research and development on a display device is continuously being conducted.

The display device is desired to have sufficient impact resistance to secure device reliability. Various layers may be included in the display device to secure a physical property such as impact resistance, but in this case, concerns that an optical property of the display device may be damaged may exist.

Accordingly, a display device that may secure sufficient a physical property without damaging an optical property is desired.

### SUMMARY

A feature of the disclosure is to provide a method of manufacturing a display device, a display device, and an electronic device comprising a display device having an excellent physical property such as impact resistance without damaging an optical property.

A feature of the disclosure is to provide a method of manufacturing a display device, a display device, and an electronic device comprising a display device in which a sensing area where various pieces of input information may be sensed in a display area may be secured.

In an embodiment of the disclosure, a method of manufacturing a display device may include providing a display panel, combining a first jig with the display panel along a first combination direction, combining a second jig with the display panel along a second combination direction different from the first combination direction, and disposing a window layer including a resin material on the display panel.

In an embodiment, the providing the display panel may include providing a pixel-circuit layer including a base layer, providing a driving circuit part and light-emitting elements on the pixel-circuit layer, and defining a hole passing through the base layer. A first step may be formed in at least a partial area between the driving circuit part and the light-emitting elements. A second step may be formed in the hole and a peripheral portion of the hole.

In an embodiment, the method may further include disposing an adhesive layer on the display panel. A first end of the adhesive layer may be next to an area where the first step is formed. A second end of the adhesive layer may be next to an area where the second step is formed.

In an embodiment, the first jig may be a first step compensation jig with respect to the first step. The second jig may be a second step compensation jig with respect to the second step.

In an embodiment, the combining the first jig with the display panel may include disposing an upper arm portion of the first jig next to the adhesive layer. The upper arm portion may form a flat surface continuous with an upper surface of the adhesive layer.

In an embodiment, the combining the second jig with the display panel may include providing a hole arm portion of the second jig in the hole and disposing the hole arm portion of the second jig next to the adhesive layer. The hole arm portion may form a flat surface continuous with the upper surface of the adhesive layer. In an embodiment, the method may further include disposing a window base on the adhesive layer, the upper arm portion, and the hole arm portion.

In an embodiment, the method may further include patterning a light-blocking layer on the window base.

In an embodiment, in disposing the window base, a combination state of the first jig and the second jig to the display panel may be maintained.

In an embodiment, the disposing the window layer may include forming the resin material on the window base using jet dispensing, inkjet printing, spin coating, or slit coating.

In an embodiment, the forming the resin material may include performing a thermal curing or photocuring process on the resin material.

In an embodiment, in the disposing the window layer, a combination state of the first jig and the second jig to the display panel may be maintained.

In an embodiment, the method may further include, after the disposing the window layer, removing the first jig along a direction opposite to the first combination direction, and removing the second jig along a direction opposite to the second combination direction.

In an embodiment, the method may further include cutting at least a portion of edge portions of the window layer.

In an embodiment of the disclosure, a display device may include a display area and a sensing area formed inside the display area, a display panel including a base layer disposed across the display area and including a hole overlapping the sensing area, and a light-emitting element disposed on the base layer in the display area, a sensor disposed in the sensing area, a window base disposed on the display panel, and including at least a portion disposed in the display area and covering the sensing area, and a window layer including at least a portion disposed in the display area and covering the sensing area, disposed on the window base, and including a resin material.

In an embodiment, the display device may further include a non-display area disposed in a peripheral portion of the display area, and a driving circuit part in the non-display area. A step may be formed in an area between the driving circuit part and the light-emitting element.

In an embodiment, the sensor may obtain sensing information based on light information or the like and may be disposed under the base layer.

In an embodiment, the display device may further include an adhesive layer disposed on the display panel and bonding the display panel and the window base. The window base and the window layer may cover an area wider than an area of the display panel.

In an embodiment, the adhesive layer may include optically clear adhesive (“OCA”) or optically clear resin (“OCR”). The window base may include polyethylene terephthalate (“PET”).

In an embodiment, the display device may further include a light-blocking layer disposed on the window base and including at least a portion disposed around the sensing area.

In an embodiment of the disclosure, an electronic device may comprise a processor configured to provide input image data; a display device configured to display an image based on the input image data, the display device including sub-pixel areas; and a power supply configured to supply power to the display device. The display device may comprise: a display area and a sensing area formed inside the display area; a display panel including: a base layer which is disposed across the display area and in which a hole overlapping the sensing area is defined; and a light-emitting element disposed on the base layer in the display area; a sensor disposed in the sensing area; a window base disposed on the display panel, and including at least a portion disposed in the display area and covering the sensing area; and a window layer including at least a portion disposed in the display area and covering the sensing area, disposed on the window base, and including a resin material.

In an embodiment of the disclosure, a method of manufacturing a display device, a display device, and an electronic device comprising a display device having an excellent physical property such as impact resistance without damaging an optical property may be provided.

In an embodiment of the disclosure, a method of manufacturing a display device, a display device, and an electronic device comprising a display device in which a sensing area where various pieces of input information may be sensed in a display area may be secured may be provided.

### BRIEF DESCRIPTION OF THE DRAWINGS

The above and other features of the disclosure will become more apparent by describing in further detail embodiments thereof with reference to the accompanying drawings, in which:

FIG. 1 is a schematic plan view illustrating an embodiment of a display device;

FIG. 2 and FIG. 3 are schematic cross-sectional views illustrating an embodiment of a display device;

FIG. 4 is a schematic cross-sectional view illustrating an embodiment of a display device; and

FIGS. 5 to 9 are schematic cross-sectional views for each process operation illustrating an embodiment of a method of manufacturing a display device.

FIG. 10 is a schematic block diagram illustrating an electronic device including a display device in accordance with an embodiment.

FIG. 11 is a schematic diagram illustrating an example where the electronic device of FIG. 10 is implemented as a smartphone.

FIG. 12 is a schematic diagram illustrating an example where the electronic device of FIG. 10 is implemented as a tablet computer.

### DETAILED DESCRIPTION OF THE EMBODIMENT

The disclosure may be modified in various manners and have various forms. Therefore, illustrative embodiments will be illustrated in the drawings and will be described in detail in the specification. However, it should be understood that the disclosure is not intended to be limited to the disclosed specific forms, and the disclosure includes all modifications, equivalents, and substitutions within the spirit and technical scope of the disclosure.

Terms of “first”, “second”, and the like may be used to describe various components, but the components should not be limited by the terms. The terms are used only for the purpose of distinguishing one component from another component. For example, without departing from the scope of the disclosure, a first component may be referred to as a second component, and similarly, a second component may also be referred to as a first component. In the following description, the singular expressions include plural expressions unless the context clearly dictates otherwise.

It should be understood that in the application, a term of “include”, “have”, or the like is used to specify that there is a feature, a number, a step, an operation, a component, a part, or a combination thereof described in the specification, but does not exclude a possibility of the presence or addition of one or more other features, numbers, steps, operations, components, parts, or combinations thereof in advance. In addition, a case where a portion of a layer, a layer, an area, a plate, or the like is referred to as being “on” another portion, it includes not only a case where the portion is “directly on” another portion, but also a case where there is further another portion between the portion and the other portion. In addition, in the specification, when a portion of a layer, a layer, an area, a plate, or the like is formed on another portion, a forming direction is not limited to an upper direction but includes forming the portion on a side surface or in a lower direction. On the contrary, when a portion of a layer, a layer, an area, a plate, or the like is formed “under” another portion, this includes not only a case where the portion is “directly beneath” another portion but also a case where there is further another portion between the portion and the other portion.

The disclosure relates to a method of manufacturing a display device, the display device, and an electronic device comprising the display device. Hereinafter, a method of manufacturing a display device, the display device, and an electronic device comprising the display device in an embodiment are described with reference to the accompanying drawings.

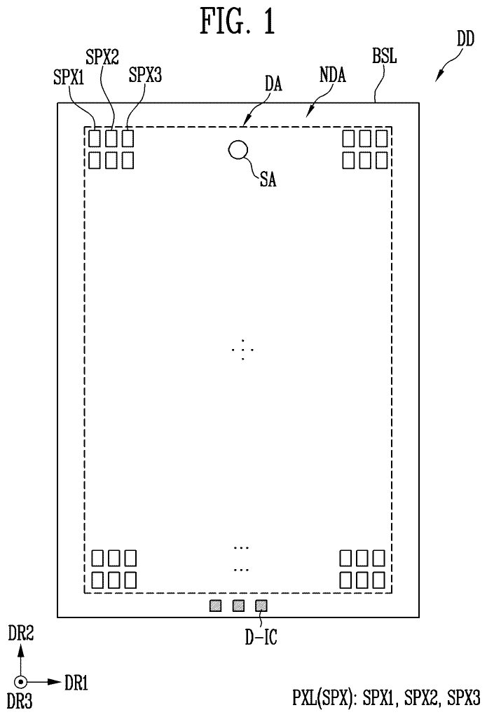

FIG. 1 is a schematic plan view illustrating an embodiment of a display device.

Referring to FIG. 1, the display device DD may include a base layer BSL and a pixel PXL disposed on the base layer BSL. The display device DD may include a driving circuit part D-IC, lines, and pads.

The display device DD (or the base layer BSL) may include a display area DA and a non-display area NDA. The non-display area NDA may mean an area other than an area of the display area DA. The non-display area NDA may surround at least a portion of the display area DA.

The base layer BSL may form a base surface of the display device DD. The base layer BSL may be a rigid or flexible substrate or film. In an embodiment, the base layer BSL may include a glass material, for example. However, the disclosure is not limited thereto. In an embodiment, the base layer BSL may include a silicon material. In an alternative embodiment, the base layer BSL may include polyimide.

The display area DA may mean an area where the pixel PXL is disposed. The non-display area NDA may mean an area where the pixel PXL is not disposed. The driving circuit part, the line, and the pads connected to the pixel PXL of the display area DA may be disposed in the non-display area NDA.

In an embodiment, the pixel PXL (or sub-pixels SPX) may be disposed according to a stripe or PENTILE™ arrangement structure, but are not limited thereto, and various embodiments may be applied to the disclosure.

In an embodiment, the pixel PXL (or the sub-pixels SPX) may include a first sub-pixel SPX1, a second sub-pixel SPX2, and a third sub-pixel SPX3. Each of the first sub-pixel SPX1, the second sub-pixel SPX2, and the third sub-pixel SPX3 may be a sub-pixel. At least one of the first sub-pixel SPX1, the second sub-pixel SPX2, and the third sub-pixel SPX3 may form one pixel unit capable of emitting light of various colors.

Each of the first sub-pixel SPX1, the second sub-pixel SPX2, and the third sub-pixel SPX3 may emit light of one color.

In an embodiment, the first sub-pixel SPX1 may be a red pixel emitting light of red (e.g., first color), the second sub-pixel SPX2 may be a green pixel emitting light of green (e.g., second color), and the third sub-pixel SPX3 may be a blue pixel emitting light of blue (e.g., third color), for example. The red pixel may provide light of a wavelength range of 600 nanometers (nm) to 750 nm. The green pixel may provide light of a wavelength band of 480 nm to 560 nm. The blue pixel may provide light of a wavelength range of 370 nm to 460 nm.

In an embodiment, the number of second sub-pixels SPX2 may be greater than the number of first sub-pixels SPX1 and the number of third sub-pixels SPX3. However, the color, type, number, and/or the like of the first sub-pixel SPX1, the second sub-pixel SPX2, and the third sub-pixel SPX3 forming each pixel unit are/is not limited to a particular embodiment.

The driving circuit D-IC may be disposed on one side of the display area DA. The driving circuit D-IC may be disposed in the non-display area NDA.

The driving circuit D-IC may include a scan driver and a data driver. The scan driver may supply a scan signal to the pixel PXL. The data driver may supply a data signal to the pixel PXL. In an embodiment, the pixel PXL may be electrically connected to the driving circuit part D-IC and may emit light based on an electrical signal provided from the driving circuit part D-IC.

The display device DD (or the base layer BSL) may include a sensing area SA. The sensing area SA may be an area capable of obtaining sensing information based on various pieces of light information or the like.

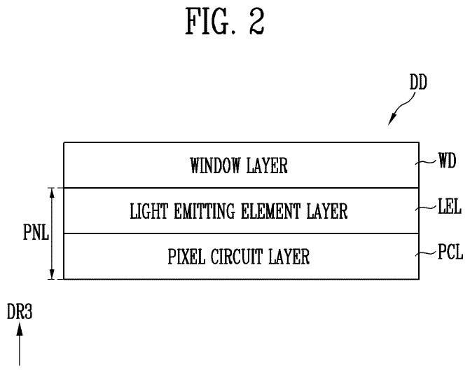

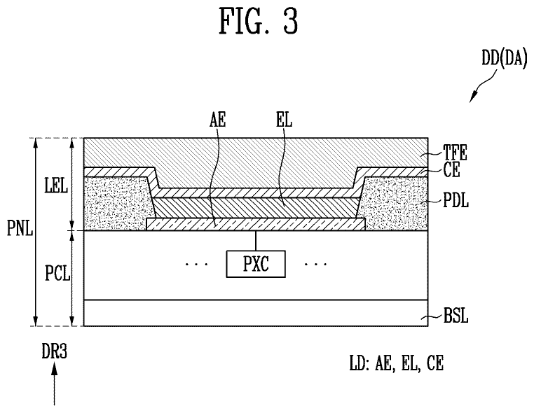

In an embodiment, the sensing area SA may be disposed in the display area DA. The sensing area SA may be surrounded by the display area DA. In an embodiment, a position of the sensing area SA may be appropriately changed, and the number of areas in which the sensing area SA is disposed is not limited to a particular embodiment. FIGS. 2 and 3 are schematic cross-sectional views illustrating an embodiment of a display device. FIG. 3 shows a portion of the display device DD in the display area DA.

Referring to FIGS. 2 and 3, the display device DD may include a display panel PNL and a window layer WD on the display panel PNL. The display panel PNL may include a pixel-circuit layer PCL and a light-emitting element layer LEL.

The pixel-circuit layer PCL may include the base layer BSL. The pixel-circuit layer PCL may be a layer including a pixel circuit PXC. The pixel-circuit layer PCL may be a backplane layer. The pixel circuit PXC may be formed on the base layer BSL and may drive a light-emitting element LD. The pixel-circuit layer PCL may include conductive layers and insulating layers, and the conductive layers may form the pixel circuit PXC. The pixel circuit PXC may include circuit elements. The circuit elements may include a driving transistor and may also include additional transistor and capacitors.

The light-emitting element layer LEL may be disposed on the pixel-circuit layer PCL. The light-emitting element layer LEL may include the light-emitting element LD. The light-emitting element layer LEL may further include a pixel defining layer PDL and an encapsulation layer TFE.

The light-emitting element LD may be electrically connected to the pixel circuit PXC. In an embodiment, the light-emitting element LD may include an organic light-emitting diode (“OLED”) including an organic material. In an alternative embodiment, the light-emitting element LD may include an inorganic light-emitting diode including an inorganic material, for example. However, the disclosure is not limited thereto. For convenience of description in this specification, the disclosure is described based on an embodiment in which the light-emitting element LD is the OLED.

The light-emitting element LD may include an anode electrode AE, a light-emitting structure EL, and a cathode electrode CE. In an embodiment, the light-emitting structure EL may be disposed in an area defined by the pixel defining layer PDL. The pixel defining layer PDL may be next (adjacent) to a periphery of the light-emitting structure EL. One surface of the light-emitting structure EL may be electrically connected to the anode electrode AE, and another surface of the light-emitting structure EL may be electrically connected to the cathode electrode CE. The anode electrode AE and the cathode electrode CE may include various conductive materials.

The light-emitting structure EL may include a plurality of layers. In an embodiment, the light-emitting structure EL may include a plurality of light-emitting structures including a hole transport part, a light-emitting layer (or a light generation layer), and an electron transport part, for example. In an embodiment, each of the layers forming the light-emitting structure may include an organic material, and may further include an inorganic material such as a metal-including or consisting of compound or a quantum dot.

The hole transport part may include a multilayer structure having a plurality of layers respective including different materials from each other. In an embodiment, the hole transport part may include a hole injection layer and a hole transport layer, and may further include a light-emitting auxiliary layer, an electron blocking layer, or the like, for example.

The light-emitting layer may include a material capable of emitting light of one color. The light-emitting layer may include a host and a dopant. The host of the light-emitting layer may be a light-emitting material capable of capturing carriers (an electron and a hole) for generating light, and may induce efficient generation of an exciton. The dopant may include a phosphorescent dopant or a fluorescent dopant. However, an embodiment of the dopant is not particularly limited. In an embodiment, the dopant may include an organic material, and may also include a metal complex or the like.

The electron transport part may include a multilayer structure having a plurality of layers respectively including different materials from each other. In an embodiment, the electron transport part may include an electron injection layer and an electron transport layer, and may further include an electron buffer layer, a hole blocking layer, or the like.

The pixel defining layer PDL may be disposed on the pixel-circuit layer PCL to define a position where the light-emitting structure EL is disposed. The pixel defining layer PDL may include an organic material or an inorganic material. In an embodiment, the pixel defining layer PDL may include a plurality of layers respectively including an inorganic material, for example. However, the disclosure is not limited thereto.

The encapsulation layer TFE may be disposed on the light-emitting element LD (e.g., the cathode electrode CE). The encapsulation layer TFE may offset a step generated by the light-emitting element LD and the pixel defining layer PDL. The encapsulation layer TFE may include a plurality of insulating layers covering the light-emitting element LD. In an embodiment, the encapsulation layer TFE may include an inorganic layer and an organic layer. In an embodiment, the encapsulation layer TFE may have a structure in which a first inorganic layer/organic layer/second inorganic layer are sequentially disposed, for example. However, the disclosure is not limited thereto. In an embodiment, the encapsulation layer TFE may be a thin film encapsulation layer.

The window layer WD may be disposed on the display panel PNL (e.g., the light-emitting element layer LEL). The window layer WD may protect the display panel PNL from an external factor and may transmit light.

The window layer WD may include a resin material. In an embodiment, the window layer WD may be manufactured based on a resin material. In an embodiment, the window layer WD may include polyurethane resin, polyimide resin, epoxy resin, acrylic resin, polycarbonate resin, or polymethyl methacrylate resin, for example. However, the disclosure is not limited thereto. In this case, excellent impact resistance for the display device DD may be provided, and a flexibility characteristic for the display device DD may be secured.

In an embodiment, the window layer WD may include a plurality of layers. In an embodiment, the window layer WD may be provided by sequentially forming layers based on different resin materials, for example.

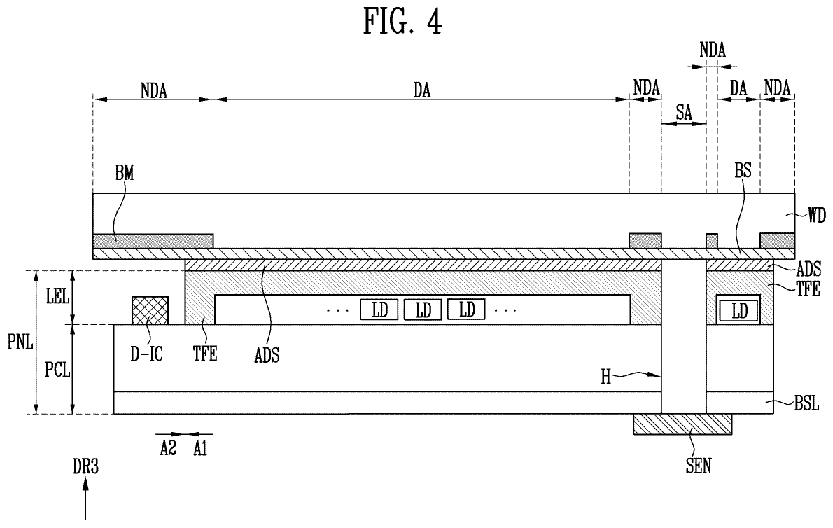

FIG. 4 is a schematic cross-sectional view illustrating an embodiment of a display device.

FIG. 4 schematically shows a stack structure of the display device DD in the display area DA, the sensing area SA, and the non-display area NDA.

Referring to FIG. 4, the base layer BSL may be disposed across the display area DA, the non-display area NDA, and the sensing area SA.

In an embodiment, the base layer BSL may overlap the sensing area SA and include a hole H defined in the sensing area SA. In an embodiment, the hole H may pass through the pixel-circuit layer PCL.

In an embodiment, the display device DD may include a sensor SEN.

The sensor SEN may obtain sensing information based on light information or the like. In an embodiment, the sensor SEN may be disposed under the display panel PNL (e.g., the base layer BSL) in a partial area of the display area DA, for example.

The sensor SEN may be one of various sensors obtaining the sensing information based on applied light. In an embodiment, the sensor SEN may include at least one of an optical fingerprint sensor, an illuminance sensing sensor, a proximity sensing sensor, a camera module, and a light sensor, for example.

In an embodiment, the sensor SEN may be disposed in the sensing area SA in which the hole H is formed, and thus may output the sensing information based on information (e.g., light or the like) applied from an outside.

In an embodiment, the light-emitting elements LD may be disposed in the display area DA, and the light-emitting elements LD may be encapsulated by the encapsulation layer TFE.

In an embodiment, the driving circuit part D-IC may be disposed on the pixel-circuit layer PCL (e.g., the base layer BSL) in the non-display area NDA. In an embodiment, the light-emitting element LD and layers next (adjacent) thereto may not be disposed in a peripheral portion of the driving circuit part D-IC, and thus a step may be formed between the non-display area NDA and the display area DA.

In an embodiment, layers of the cathode electrode CE, the encapsulation layer TFE, or the like may not be disposed on the driving circuit part D-IC, for example. In an embodiment, a step may be formed between a first area A1 and a second area A2 distinguished based on an edge portion of the encapsulation layer TFE. In an embodiment, a step may be formed in at least a portion of an area between the driving circuit D-IC and the light-emitting element LD, for example.

In an embodiment, as the hole H is defined for the sensor SEN to suitably receive light, a step may be formed in the hole H and a peripheral portion of the hole H.

In an embodiment, the display device DD may include an adhesive layer ADS, a window base BS, and a light-blocking layer BM.

The adhesive layer ADS may be disposed on the encapsulation layer TFE. The adhesive layer ADS may be a layer for bonding a window base BS and layers thereunder. In an embodiment, the adhesive layer ADS may bond the display panel PNL and the window base BS, for example. In an embodiment, the adhesive layer ADS may be entirely disposed on an upper surface of the encapsulation layer TFE.

The adhesive layer ADS may include various optical adhesive materials. In an embodiment, the adhesive layer ADS may include optically clear adhesive (“OCA”) or optically clear resin (“OCR”), for example. However, the disclosure is not limited thereto.

The window base BS may be disposed across the display area DA, the non-display area NDA, and the sensing area SA. The window base BS may overlap the hole H in a plan view. The window base BS may cover the sensing area SA.

The window base BS may be a base film for manufacturing the window layer WD. The window base BS may cover an area wider than an area of the display panel PNL. In an embodiment, the display panel PNL may be entirely included in the window base BS in a plan view, for example.

In an embodiment, the window base BS may include a film including various organic materials. In an embodiment, the window base BS may include polyethylene terephthalate (“PET”), for example. However, the disclosure is not limited to a particular embodiment.

The light-blocking layer BM may be disposed on the window base BS. In an embodiment, the light-blocking layer BM may be disposed in the non-display area NDA. The light-blocking layer BM may be disposed in a peripheral portion of the sensing area SA. The light-blocking layer BM may include various light-blocking materials such as carbon black.

The window layer WD may be disposed on the window base BS. The window layer WD may be disposed across the display area DA, the non-display area NDA, and the sensing area SA. In an embodiment, the window layer WD may cover the light-blocking layer BM.

The window layer WD may cover an area wider than an area of the display panel PNL. In an embodiment, in a plan view, the display panel PNL may be entirely included in the window layer WD, for example.

As described above, the window layer WD may include a resin material, and thus, the display device DD having an excellent physical property such as impact resistance may be provided.

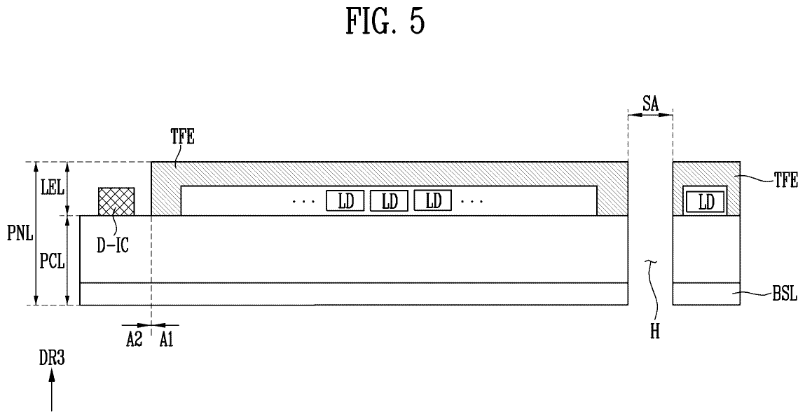

Referring to FIGS. 5 to 9, a method of manufacturing a display device DD in an embodiment is described. For convenience of description, a contents that may overlap the content described above is briefly described or is not repeated.

FIGS. 5 to 9 are schematic cross-sectional views for an embodiment of each process operation illustrating a method of manufacturing a display device. For convenience of description, FIGS. 5 to 9 are shown based on the cross-sectional view shown in FIG. 4.

Referring to FIG. 5, the display panel PNL may be provided. In an embodiment, in order to manufacture the display panel PNL, conductive layers, insulating layers, and semiconductor layers may be patterned on the base layer BSL to provide the pixel-circuit layer PCL, the light-emitting elements LD may be disposed on the pixel-circuit layer PCL, and the encapsulation layer TFE sealing the light-emitting elements LD may be formed, for example.

In this operation, the light-emitting elements LD may be manufactured based on various methods such as deposition, and the encapsulation layer TFE may be formed to expose the driving circuit D-IC or the like and cover the light-emitting elements LD. Accordingly, a step may be formed between the first area A1 and the second area A2 (e.g., in a peripheral portion of the display area DA).

In this operation, after the encapsulation layer TFE is manufactured, the hole H at least passing through the base layer BSL may be formed. Accordingly, the hole H in which the sensor area SA may be formed may be provided. As the hole H is formed, a step may be formed in the hole H and the peripheral portion of the hole H.

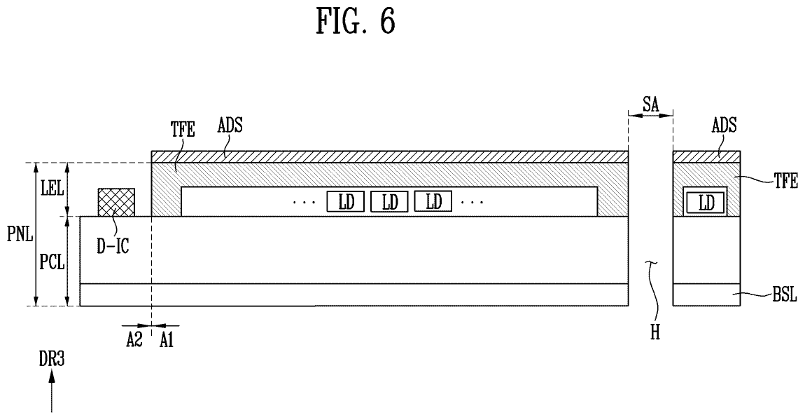

Referring to FIG. 6, the adhesive layer ADS may be disposed on the display panel PNL (e.g., the encapsulation layer TFE). The adhesive layer ADS may not be disposed in at least a portion of the non-display area NDA and an area where the hole H is disposed. Accordingly, the adhesive layer ADS may form an adhesive surface on which the window base BS may be disposed.

In this operation, an end of the adhesive layer ADS may be formed next (adjacent) to an area where the step is formed. In an embodiment, a first end of the adhesive layer ADS may be next (adjacent) to an edge portion of the encapsulation layer TFE, and a second end of the adhesive layer ADS may be next (adjacent) to the hole H, for example.

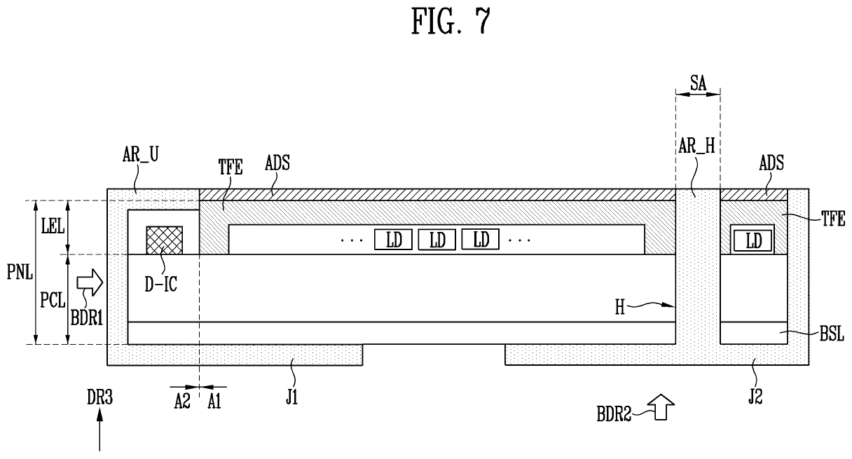

Referring to FIG. 7, a first jig (also referred to as a first step compensation jig) J1 and a second jig (second step compensation jig) J2 having different structures may be combined with the display panel PNL.

In this operation, the first jig J1 may be combined with the display panel PNL along a first combination direction BDR1. In an embodiment, the first jig J1 may be combined with the display panel PNL along a plane direction where the base layer BSL is disposed, for example.

In an embodiment, the first jig J1 may be a step compensation jig for a step (also referred to as a first step) formed between the first area A1 and the second area A2.

In an embodiment, the light-emitting elements LD, the encapsulation layer TFE, and the adhesive layer ADS may be disposed on the pixel-circuit layer PCL in the first area A1, and thus an upper surface of the adhesive layer ADS may be formed at one height. Since the light-emitting elements LD, the encapsulation layer TFE, and the adhesive layer ADS are not disposed on the pixel-circuit layer PCL in the second area A2, separate configurations may not be formed at the above-described height.

In this operation, an upper arm portion AR_U of the first jig J1 may be disposed next (adjacent) to the adhesive layer ADS so that a continuous upper surface is formed between the first area A1 and the second area A2. In an embodiment, the first jig J1 may be combined with the display panel PNL, and an upper surface of the upper arm portion AR_U and the upper surface of the adhesive layer ADS may form a continuous flat surface.

In this operation, the second jig J2 may be combined with the display panel PNL along a second combination direction BDR2 different from the first combination direction BDR1. In an embodiment, the second jig J2 may be combined with the display panel PNL along a thickness direction (e.g., a third direction DR3) of the base layer BSL, for example.

In an embodiment, the second jig J2 may be a step compensation jig for a step (also referred to as a second step) formed by the hole H.

In an embodiment, as the hole H at least passing through the base layer BSL is formed, a step may be formed in the hole H and the peripheral portion of the hole H.

In this operation, a hole arm portion AR_H of the second jig J2 may be provided inside the hole H. The hole arm portion AR_H of the second jig J2 may be disposed next (adjacent) to the adhesive layer ADS so that a continuous upper surface is formed in the hole H and the peripheral portion of the hole H. In an embodiment, the second jig J2 may be combined with the display panel PNL, and an upper surface of the upper arm portion AR_U and the upper surface of the adhesive layer ADS may form a continuous flat surface.

Accordingly, in this operation, a step formed by at least a portion of the non-display area NDA and the hole H may be compensated for by the first and second jigs J1 and J2, and a generally flat surface may be formed.

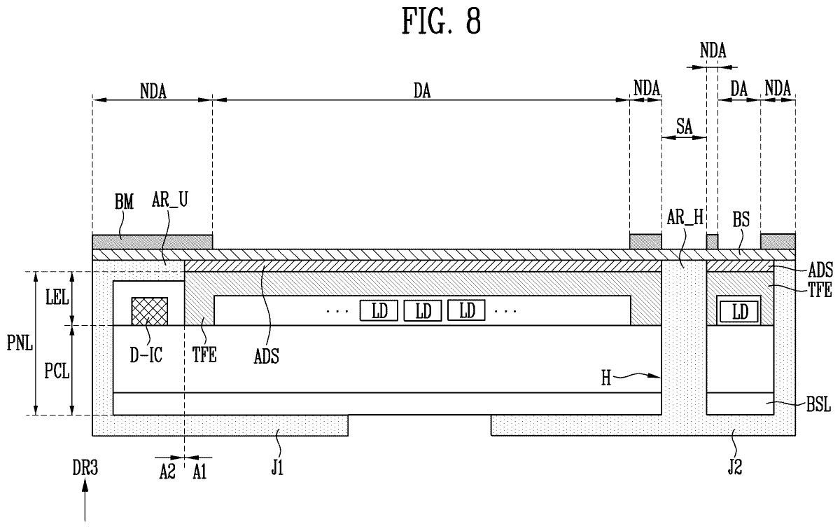

Referring to FIG. 8, the window base BS may be disposed on a surface formed by the first and second jigs J1 and J2 and the adhesive layer ADS, and the light-blocking layer BM may be patterned on the window base BS.

In this operation, the window base BS may be disposed on the adhesive layer ADS, the upper arm portion AR_U, and the hole arm portion AR_H.

In this operation, the window base BS may be disposed on a planarization surface formed in the process operations described above. In addition, the light-blocking layer BM may be patterned, and thus the non-display area NDA may be defined.

However, in an embodiment, the window base BS where the light-blocking layer BM is patterned may be separately prepared, and the window base BS where the light-blocking layer BM is patterned may be prepared together on the planarization surface formed in the process operations described above.

In this operation, the first and second jigs J1 and J2 may maintain a combination state for the display panel PNL.

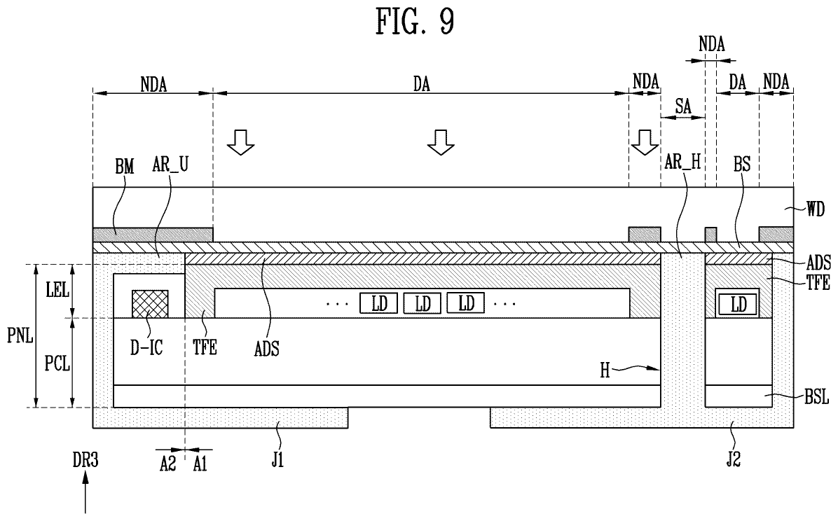

Referring to FIG. 9, the window layer WD may be formed on the window base BS.

In this operation, the window layer WD may be directly disposed on the window base BS. As described above, since steps in the display panel PNL may be compensated by the first and second jigs J1 and J2, the window base BS may be disposed on a generally flat surface, and the window layer WD may be stably formed on the window base BS.

In this operation, the window layer WD may be formed on the window base BS using various resin compositions. In an embodiment, a resin material for manufacturing the window layer WD may be formed on the window base BS by a process such as jet dispensing, inkjet printing, spin coating, or slit coating.

In an embodiment, a layer manufactured based on the resin composition may be cured by photocuring using ultraviolet (“UV”) light or thermal curing at a temperature of 80 degrees Celsius (C) or lower, and the manufactured window layer WD may have a transmittance of 90% or more with respect to light of a visible light wavelength band so as to output light provided by the light-emitting element LD.

In this operation, the first and second jigs J1 and J2 may maintain a combination state to the display panel PNL.

Referring to FIG. 4 together, the first and second jigs J1 and J2 may be removed from the display panel PNL. In an embodiment, the first jig J1 may be removed along a direction opposite to the first combination direction BDR1 defined when combined with the display panel PNL. In an embodiment, the second jig J2 may be removed along a direction opposite to the second combination direction BDR2 defined when combined with the display panel PNL.

Referring to FIG. 4 together, in an embodiment, the sensor SEN may be disposed under the base layer BSL. In an embodiment, the sensor SEN and a lower base on which the sensor SEN is disposed may be further disposed.

Thereafter, in an embodiment, a cutting process (e.g., laser cutting or mechanical wheel cutting) may be performed on edge portions of the window layer WD or the like to adjust a dimension of the window layer WD or the like, and the display device DD in an embodiment may be provided.

Hereinafter, an electronic device 1000 including the display device DD in accordance with an embodiment will be described.

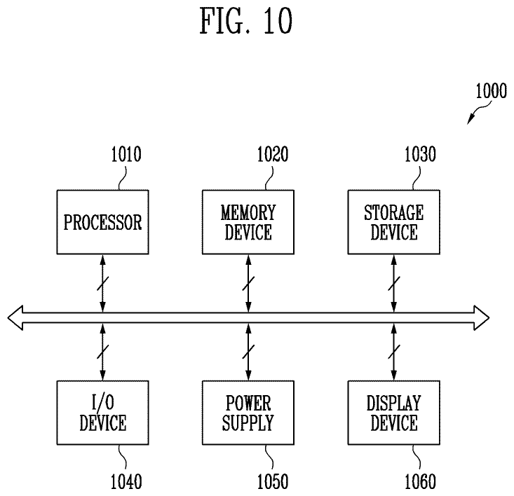

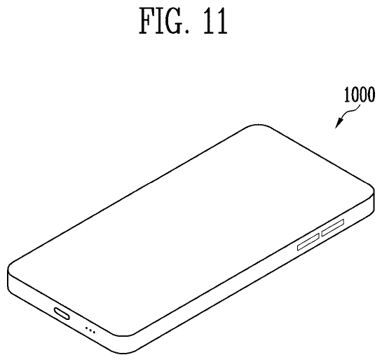

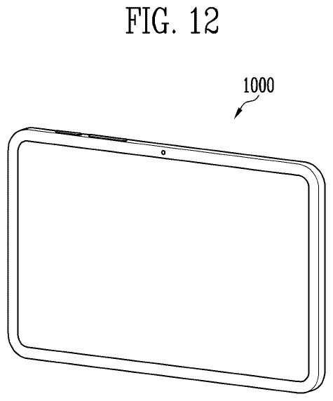

FIG. 10 is a schematic block diagram illustrating an electronic device 1000 including a display device in accordance with an embodiment. FIG. 11 is a schematic diagram illustrating an example where the electronic device 1000 of FIG. 10 is implemented as a smartphone. FIG. 12 is a schematic diagram illustrating an example where the electronic device 1000 of FIG. 10 is implemented as a tablet computer.

Referring to FIGS. 10 to 12, the electronic device 1000 may include a processor 1010, a memory device 1020, a storage device 1030, an input/output (I/O) device 1040, a power supply 1050, and a display device 1060. The display device 1060 may be the display device DD of FIG. 1. The electronic device 1000 may further include various ports for communication with a video card, a sound card, a memory card, a USB device, or other systems. In an embodiment, as illustrated in FIG. 20, the electronic device 1000 may be implemented as a smartphone. In an embodiment, as illustrated in FIG. 21, the electronic device 1000 may be implemented as a tablet computer. However, the aforementioned examples are illustrative, and the electronic device 1000 is not necessarily limited to the aforementioned examples. For example, the electronic device 1000 may be implemented as a cellular phone, a video phone, a smartpad, a smartwatch, a navigation device for vehicles, a computer monitor, a laptop computer, a head-mounted display device, or the like.

The processor 1010 may perform specific calculations or tasks. In an embodiment, the processor 1010 may be a micro-processor, a central processing unit, an application processor, or the like. The processor 1010 may be connected to other components through an address bus, a control bus, a data bus, and the like. In an embodiment, the processor 1010 may be connected to an expansion bus such as a peripheral component interconnect (PCI) bus. In an embodiment, the processor 1010 may provide input image data to the display device 1060. Hence, the display device 1060 may display an image based on the input image data provided from the processor 1010.

The memory device 1020 may store data needed to perform the operation of the electronic device 1000. The memory device 1020 may function as a working memory and/or a buffer memory for the processor 1010. For example, the memory device 1020 may include one or more volatile memory devices such as a dynamic random access memory (DRAM) device, a static random access memory (SRAM) device, and a mobile DRAM device.

The storage device 1030 may store data in response to control signals or data from the processor 1010. The storage device 1030 may include one or more non-volatile storages to retain the data even when the electronic device 1000 is powered off. In some embodiments, the storage device 1030 may include a solid state drive (SSD), a hard disk drive (HDD), a CD-ROM, or the like.

The I/O device 1040 may include input devices such as a keyboard, a keypad, a touchpad, a touch screen, and a mouse, and output devices such as a speaker and a printer. In an embodiment, the display device 1060 may be included in the I/O device 1040.

The power supply 1050 may supply power needed to perform the operation of the electronic device 1000. For example, the power supply 1050 may be a power management integrated circuit (PMIC). In an embodiment, the power supply 1050 may supply power to the display device 1060.

The display device 1060 may display an image corresponding to visual information of the electronic device 1000. The display device 1060 may be connected to other components through the buses or other communication links.

As described above, although the disclosure has been described with reference to the preferred embodiment above, those skilled in the art or those having a common knowledge in the art will understand that the disclosure may be variously modified and changed without departing from the spirit and technical area of the disclosure described in the claims which will be described later.

Therefore, the technical scope of the disclosure should not be limited to the contents described in the detailed description of the specification, but should be defined by the claims.

What is claimed is:

1. A method of manufacturing a display device, the method comprising:
providing a display panel;
combining a first jig with the display panel along a first combination direction;
combining a second jig with the display panel along a second combination direction different from the first combination direction; and
disposing a window layer including a resin material on the display panel.

2. The method according to claim 1, wherein the providing the display panel comprises:
providing a pixel-circuit layer including a base layer;
providing a driving circuit part and light-emitting elements on the pixel-circuit layer; and
defining a hole passing through the base layer,
a first step is formed in at least a partial area between the driving circuit part and the light-emitting elements, and
a second step is formed in the hole and a peripheral portion of the hole.

3. The method according to claim 2, further comprising:
disposing an adhesive layer on the display panel,
wherein a first end of the adhesive layer is next to an area where the first step is formed, and
a second end of the adhesive layer is next to an area where the second step is formed.

4. The method according to claim 3, wherein the first jig is a first step compensation jig with respect to the first step, and
the second jig is a second step compensation jig with respect to the second step.

5. The method according to claim 4, wherein the combining the first jig with the display panel comprises disposing an upper arm portion of the first jig next to the adhesive layer, and
the upper arm portion forms a flat surface continuous with an upper surface of the adhesive layer.

6. The method according to claim 5, wherein the combining the second jig with the display panel comprises providing a hole arm portion of the second jig in the hole and disposing the hole arm portion of the second jig next to the adhesive layer, and
the hole arm portion forms a flat surface continuous with the upper surface of the adhesive layer.

7. The method according to claim 6, further comprising:
disposing a window base on the adhesive layer, the upper arm portion, and the hole arm portion.

8. The method according to claim 7, further comprising:
patterning a light-blocking layer on the window base.

9. The method according to claim 7, wherein in the disposing the window base, a combination state of the first jig and the second jig to the display panel is maintained.

10. The method according to claim 9, wherein the disposing the window layer comprises forming the resin material on the window base using jet dispensing, inkjet printing, spin coating, or slit coating, and
the forming the resin material comprises performing a thermal curing or photocuring process on the resin material.

11. The method according to claim 10, wherein in the disposing the window layer, the combination state of the first jig and the second jig to the display panel is maintained.

12. The method according to claim 1, further comprising, after the disposing the window layer:
removing the first jig along a direction opposite to the first combination direction; and
removing the second jig along a direction opposite to the second combination direction.

13. The method according to claim 12, further comprising:
cutting at least a portion of edge portions of the window layer.

14. A display device comprising:
a display area and a sensing area formed inside the display area;
a display panel including:
a base layer which is disposed across the display area and in which a hole overlapping the sensing area is defined; and
a light-emitting element disposed on the base layer in the display area;
a sensor disposed in the sensing area;
a window base disposed on the display panel, and including at least a portion disposed in the display area and covering the sensing area; and
a window layer including at least a portion disposed in the display area and covering the sensing area, disposed on the window base, and including a resin material.

15. The display device according to claim 14, further comprising:
a non-display area disposed in a peripheral portion of the display area; and
a driving circuit part in the non-display area,
wherein a step is formed in an area between the driving circuit part and the light-emitting element.

16. The display device according to claim 14, wherein the sensor may obtain sensing information based on light information and is disposed under the base layer.

17. The display device according to claim 14: further comprising:
an adhesive layer disposed on the display panel and bonding the display panel and the window base,
wherein the window base and the window layer cover an area wider than an area of the display panel.

18. The display device according to claim 17, wherein the adhesive layer includes optically clear adhesive or optically clear resin, and
the window base includes polyethylene terephthalate.

19. The display device according to claim 17, further comprising:
a light-blocking layer disposed on the window base and including at least a portion disposed around the sensing area.

20. An electronic device, comprising:
a processor configured to provide input image data;
a display device configured to display an image based on the input image data, the display device including sub-pixel areas; and
a power supply configured to supply power to the display device,
wherein the display device comprises:
a display area and a sensing area formed inside the display area;
a display panel including:
a base layer which is disposed across the display area and in which a hole overlapping the sensing area is defined; and
a light-emitting element disposed on the base layer in the display area;
a sensor disposed in the sensing area;
a window base disposed on the display panel, and including at least a portion disposed in the display area and covering the sensing area; and
a window layer including at least a portion disposed in the display area and covering the sensing area, disposed on the window base, and including a resin material.
